(19) United States
(12) Patent Application Publication
(10) Pub. No.: US 2024/0224493 A1
(43) Pub. Date: Jul. 4, 2024

(54) DYNAMIC RANDOM ACCESS MEMORY DEVICE AND METHOD FOR FORMING THE SAME

(71) Applicant: Powerchip Semiconductor Manufacturing Corporation, Hsinchu (TW)

(72) Inventor: Wen-Yueh Chang, Hsinchu City (TW)

(73) Assignee: Powerchip Semiconductor Manufacturing Corporation, Hsinchu (TW)

(21) Appl. No.: 18/319,422

(22) Filed: May 17, 2023

(30) Foreign Application Priority Data
Jan. 4, 2023 (TW) 112100175

(51) Int. Cl. H10B 12/00

(52) U.S. Cl. CPC H10B 12/00

(57) ABSTRACT

A dynamic random access memory (DRAM) device includes a substrate, multiple write word lines, multiple read word lines, multiple write bit lines, multiple read bit lines, and multiple memory device layers and a method forms the same. The write word lines and the read word lines extend toward a first direction. The write bit lines and the read bit lines extend toward a second direction, and the second direction is orthogonal to the first direction. The memory device layers are disposed on the substrate and are stacked along a normal direction of the substrate, and each of the memory device layers includes multiple memory cells. The memory cells include write transistors and read transistors, wherein a source of the corresponding write transistor is electrically connected to a gate of the corresponding read transistor to form a storage node.

### CROSS-REFERENCE TO RELATED APPLICATION

This application claims the priority benefit of Taiwan application serial no. 112100175, filed on Jan. 4, 2023. The entirety of the above-mentioned patent application is hereby incorporated by reference herein and made a part of this specification.

### BACKGROUND

### Technical Field

The disclosure relates to a dynamic random access memory (DRAM) device and a method for forming the same, and in particular to a DRAM device with a 2T0C structure and a method for forming the same.

### Description of Related Art

With the advancement of semiconductor technology, the size of a DRAM device is developing in the direction of continuous reduction, so that the occupied area of the DRAM device may be reduced and the density of the DRAM device may be increased, thereby increasing the device density. Therefore, it is one of the current development goals to seek how to further reduce the occupied area of the DRAM device so as to increase the density thereof.

### SUMMARY

The disclosure provides a dynamic random access memory (DRAM) device and a method for forming the same, and the density of the memory device may be further improved.

A DRAM device according to an embodiment of the disclosure includes a substrate, multiple write word lines, multiple read word lines, multiple write bit lines, multiple read bit lines, and multiple memory device layers. The write word lines and the read word lines extend toward a first direction. The write bit lines and the read bit lines extend toward a second direction, and the second direction is orthogonal to the first direction. The memory device layers are disposed on the substrate and are stacked along a normal direction of the substrate, and each of the memory device layers includes multiple memory cells. The memory cells include write transistors and read transistors. The write transistor is electrically connected to the corresponding write word line and the corresponding write bit line, and the read transistor is electrically connected to the corresponding read word line and the corresponding read bit line. A source of the write transistor is electrically connected to a gate of the read transistor to form a storage node.

A method for forming a DRAM device according to an embodiment of the disclosure includes the following steps. A substrate having a trench is provided, a source of a write transistor and a read word line are disposed in the trench, and the read word line extends toward a first direction and includes a source of a read transistor. A write word line and a gate of the read transistor are formed on the substrate, the write word line extends toward the first direction and includes a gate of the write transistor, and the gate of the read transistor is connected to the source of the write transistor to form a storage node. An active layer of the write transistor and an active layer of the read transistor are formed on the substrate. A write bit line and a read bit line are formed on the substrate to form a memory device layer, the write bit line and the read bit line extend toward a second direction, and the write bit line and the read bit line respectively include a drain of the write transistor and a drain of the read transistor. Multiple memory device layers are stacked in a normal direction of the substrate. A channel layer in the active layer of the write transistor and the gate of the write transistor are disposed correspondingly in the second direction, and a channel layer in the active layer of the read transistor and the gate of the read transistor are disposed correspondingly in the second direction.

A method for forming a DRAM device according to another embodiment of the disclosure includes the following steps. A substrate having a trench is provided, a gate of a read transistor and a write word line are disposed in the trench, and the write word line includes a gate of a write transistor. A first dielectric layer and an active layer of the write transistor and a first dielectric layer and an active layer of the read transistor are formed on the substrate. A source and a drain of the write transistor, a drain of the read transistor, and a read word line are formed on the substrate to form a memory device layer, the read word line extends toward a first direction and includes a source of the read transistor, and the gate of the read transistor is connected to the source of the write transistor to form a storage node. A second dielectric layer is formed on the substrate, the second dielectric layer exposes an opening for the drain of the write transistor and the drain of the read transistor to be connected to a write bit line and a read bit line, respectively. The write bit line and the read bit line are formed on the second dielectric layer, the write bit line and the read bit line extend toward a second direction, the write bit line is electrically connected to the drain of the write transistor with a first plug, and the read bit line is electrically connected to the drain of the read transistor with a second plug. Multiple memory device layers are stacked in a normal direction of the substrate.

Based on the above, some embodiments of the disclosure provide a DRAM device having a three-dimensional structure and a method for forming the same. Based on this, the disclosure may further reduce the occupied area of the DRAM device, and increase the density of the DRAM device.

### BRIEF DESCRIPTION OF THE DRAWINGS

FIG. 1A is a schematic top view of a dynamic random access memory (DRAM) device according to a first embodiment of the disclosure.

FIG. 1B is a schematic cross-sectional view taken along a section line A1-A1′ of FIG. 1A.

FIG. 1C is a schematic cross-sectional view taken along a section line A2-A2′ of FIG. 1A.

FIGS. 2A to 2C are schematic top views of a method for forming a DRAM device according to the first embodiment of the disclosure.

FIGS. 3A to 3C are each a schematic cross-sectional view taken along the section line A1-A1′ in FIGS. 2A to 2C.

FIGS. 4A to 4C are each a schematic cross-sectional view taken along the section line A2-A2′ in FIGS. 2A to 2C.

FIG. 5A is a schematic top view of a DRAM device according to a second embodiment of the disclosure.

FIG. 5B is a schematic cross-sectional view taken along a section line B1-B1′ of FIG. 5A.

FIG. 5C is a schematic cross-sectional view taken along a section line B2-B2′ of FIG. 5A.

FIGS. 6A to 6C are schematic top views of a method for forming a DRAM device according to the second embodiment of the disclosure.

FIGS. 7A to 7C are each a schematic cross-sectional view taken along a section line B1-B1′ in FIGS. 6A to 6C.

FIGS. 8A to 8C are each a schematic cross-sectional view taken along a section line B2-B2′ in FIGS. 6A to 6C.

### DESCRIPTION OF THE EMBODIMENTS

Unless otherwise defined, all terms (including technical and scientific terms) used herein have the same meaning as commonly understood by those of ordinary skill in the field to which the disclosure pertains. It will be further understood that terms such as those defined in commonly used dictionaries should be interpreted to have meanings consistent with their meanings in the context of the relevant art and the disclosure, and will not be interpreted as idealized or excessive formal meanings, unless expressly so defined herein.

The schematic diagrams herein are merely used to illustrate some embodiments of the disclosure. Therefore, the shape, number, and scale of each element shown in the schematic diagrams should not be used to limit the disclosure.

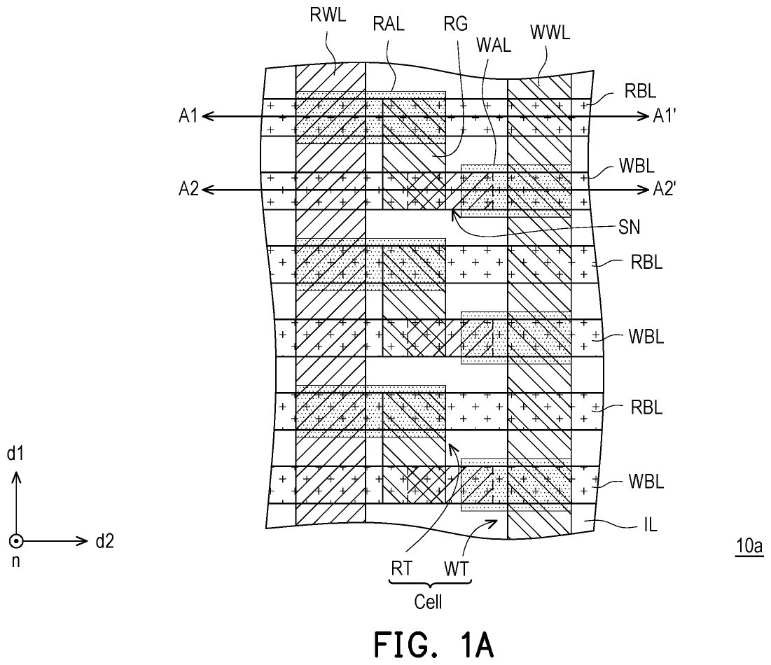

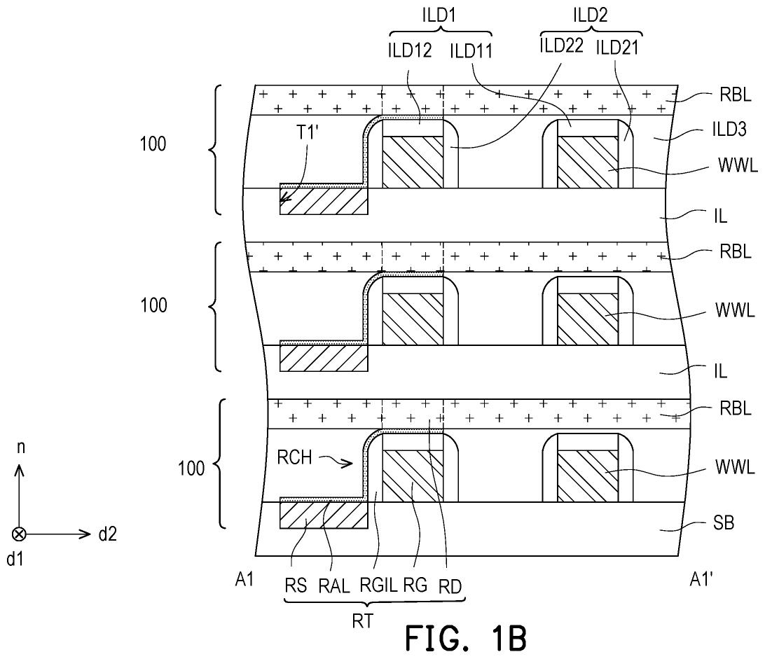

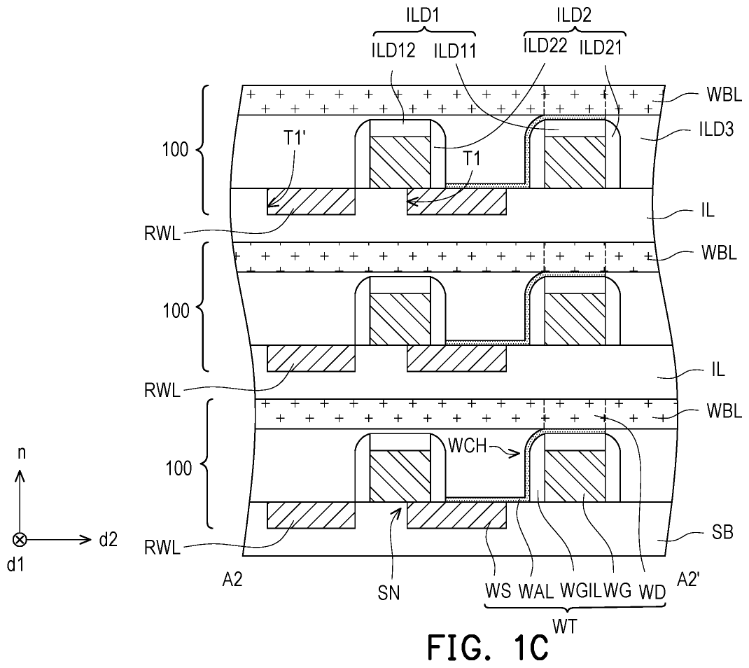

FIG. 1A is a schematic top view of a dynamic random access memory (DRAM) device according to a first embodiment of the disclosure, FIG. 1B is a schematic cross-sectional view taken along a section line A1-A1′ of FIG. 1A, and FIG. 1C is a schematic cross-sectional view taken along a section line A2-A2′ of FIG. 1A.

Please refer to FIGS. 1A, 1B, and 1C at the same time. A DRAM device 10a of the embodiment includes a substrate SB, multiple memory device layers 100, multiple write word lines WWL, multiple read word lines RWL, multiple write bit lines WBL, and multiple read bit lines RBL.

The substrate SB may be, for example, an inter layer dielectric (ILD) or an inter metal dielectric (IMD) on a semiconductor substrate or a semiconductor on insulator (SOI) substrate. The semiconductor materials in the semiconductor substrate and the SOI substrate may include, for example, elemental semiconductors, alloy semiconductors or compound semiconductors. For example, elemental semiconductors may include Si or Ge, alloy semiconductors may include SiGe, SiC, SiGeC, etc., and compound semiconductors may include III-V semiconductor materials or II-VI semiconductor materials.

The write word lines WWL are, for example, disposed on the substrate SB and extend toward a first direction d1. The material of the write word line WWL may include, for example, metal, metal compounds (such as metal nitride), alloy, semiconductor materials or a combination thereof, and the disclosure is not limited thereto.

The read word lines RWL are, for example, disposed in the substrate SB and also extend toward the first direction d1. In detail, the substrate SB of the embodiment has a trench T1 and a trench T1′, and the read word lines RWL are disposed in the trench T1′ of the substrate SB, but the disclosure is not limited thereto. The material of the read word line RWL may be the same as or similar to the material of the write word line WWL, and the descriptions are not repeated here.

The write bit lines WBL are, for example, disposed on the substrate SB and extend toward a second direction d2. The second direction d2 is, for example, orthogonal to the first direction d1. The material of the write bit line WBL may include, for example, metal, metal compounds (such as metal nitride), alloy, semiconductor materials or a combination thereof, and the disclosure is not limited thereto.

The read bit lines RBL are, for example, disposed on the substrate SB and also extend toward the second direction d2. In the embodiment, the read bit lines RBL and the write bit lines WBL belong to the same layer, the read bit lines RBL and the write bit lines WBL may be separated from each other in the first direction d1, but the disclosure is not limited thereto. The material of the read bit line RBL may be the same as or similar to the material of the write bit line WBL, and the descriptions are not repeated here.

The memory device layers 100 are, for example, disposed on the substrate SB and stacked in a normal direction n of the substrate SB. The normal direction n of the substrate SB may be, for example, orthogonal to the first direction d1 and the second direction d2. For example, FIGS. 1B and 1C show that three memory device layers 100 are sequentially stacked in the normal direction n of the substrate SB, and an isolation layer IL is disposed between adjacent memory device layers 100. The material of the isolation layer IL may include, for example, silicon oxide, silicon nitride, silicon oxynitride or a combination thereof, and the disclosure is not limited thereto. It should be noted that although FIGS. 1B and 1C merely show three memory device layers 100, the disclosure does not limit the number of memory device layers 100 included in the DRAM device 10a.

In the embodiment, each of the memory device layers 100 includes multiple memory cells Cell. Each of the memory cells Cell includes, for example, a write transistor WT and a read transistor RT. A source WS of the write transistor WT is electrically connected to a gate RG of the read transistor RT to form a storage node SN, and the presence or absence of charge in the storage node SN may be, for example, represented by digits “1” and “0”, respectively. That is, in the embodiment, the memory cell has a 2T0C (two transistors and no capacitor) structure, but the disclosure is not limited thereto. In some embodiments, the write transistor WT is electrically connected to the corresponding write word line WWL and the corresponding write bit line WBL, and the read transistor RT is electrically connected to the corresponding read word line RWL and the corresponding read bit line RBL.

In some embodiments, the write transistor WT may include a gate WG, a gate dielectric layer WGIL, a source WS, a drain WD, and an active layer WAL.

The gate WG is, for example, disposed on the substrate SB. In the embodiment, the gate WG and the write word line WWL belong to the same layer. From another perspective, the gate WG is directly connected to the write word line WWL.

The gate dielectric layer WGIL is, for example, disposed on a sidewall of the gate WG. For example, the gate dielectric layer WGIL may be disposed on the sidewall of the gate WG in the second direction d2, but the disclosure is not limited thereto. The material of the gate dielectric layer WGIL may include, for example, silicon oxide, silicon nitride, silicon oxynitride or a combination thereof, and the disclosure is not limited thereto.

The active layer WAL is, for example, disposed on the gate dielectric layer WGIL, and is, for example, disposed corresponding to the gate WG. The portion of the active layer WAL overlapping the gate WG in the second direction d2 may be, for example, a channel layer WCH. From another perspective, the gate dielectric layer WGIL is, for example, disposed between the gate WG and the channel layer WCH of the active layer WAL. In the embodiment, the material of the active layer WAL includes an oxide semiconductor. For example, the material of the active layer WAL may include indium gallium zinc oxide (IGZO), but the disclosure is not limited thereto. Since the band gap of an oxide semiconductor is larger than the band gap of silicon, when the material of the active layer WAL includes an oxide semiconductor, the write transistor WT may have a lower current in the off state (that is, having a lower leakage current), and may reduce the rate of charge loss in the storage node SN, thereby increasing the data storage time of the DRAM device 10a of the embodiment.

The source WS and the drain WD are, for example, separated from each other, and each are electrically connected to the active layer WAL. In the embodiment, the source WS is disposed in the trench T1 of the substrate SB, and the drain WD is disposed on the gate WG and belongs to the same layer as the write bit line WBL. From another perspective, the drain WD is directly connected to the write bit line WBL.

Since the channel layer WCH of the write transistor WT extends along the normal direction n of the substrate SB, and is disposed between the source WS and the drain WD in the normal direction n of the substrate SB, the write transistor WT of the embodiment is a vertical transistor, but the disclosure is not limited thereto.

In some embodiments, the read transistor RT may include a gate RG, a gate dielectric layer RGIL, a source RS, a drain RD, and an active layer RAL.

The gate RG is, for example, disposed on the substrate SB. In the embodiment, the gate RG, the gate WG, and the write word line WWL belong to the same layer.

The gate dielectric layer RGIL is, for example, disposed on a sidewall of the gate RG. For example, the gate dielectric layer RGIL may be disposed on the sidewall of the gate RG in the second direction d2, but the disclosure is not limited thereto. The material of the gate dielectric layer RGIL may be the same as or similar to the material of the gate dielectric layer WGIL, and the descriptions are not repeated here.

The active layer RAL is, for example, disposed on the gate dielectric layer RGIL, and is, for example, disposed corresponding to the gate RG. The portion of the active layer RAL overlapping the gate RG in the second direction d2 may be, for example, a channel layer RCH. From another perspective, the gate dielectric layer RGIL is, for example, disposed between the gate RG and the channel layer RCH of the active layer RAL. In the embodiment, the material of the active layer RAL also includes an oxide semiconductor, which may be the same as or similar to the material of the active layer WAL.

The source RS and the drain RD are, for example, separated from each other, and each are electrically connected to the active layer WAL. In the embodiment, the source RS is disposed in the trench T1′ of the substrate SB and belongs to the same layer as the read word line RWL, and the drain RD is disposed on the gate RG and belongs to the same layer as the read bit line RBL. From another perspective, the source RS is directly connected to the read word line RWL, and the drain RD is directly connected to the read bit line RBL.

Since the channel layer RCH of the read transistor RT extends along the normal direction n of the substrate SB, and is disposed between the source RS and the drain RD in the normal direction n of the substrate SB, the read transistor RT of the embodiment is also a vertical transistor, but the disclosure is not limited thereto.

Based on this, by making the write transistor WT and the read transistor RT have the design of a vertical transistor, the drain WD of the write transistor WT may belong to the same layer as the write bit line WBL, and the drain RD of the read transistor RT may belong to the same layer as the read bit line RBL, so that the write bit line WBL and the read bit line RBL may be directly connected to the drain WD of the write transistor WT and the drain RD of the read transistor RT, respectively. In this way, the density of the DRAM device 10a may be increased.

In some embodiments, the write transistor WT and the read transistor RT may be operated to execute a write operation and/or a read operation.

When it is desired to execute a write operation on the DRAM device 10a, the following steps may be executed, for example, but the disclosure is not limited thereto. First, a positive voltage is applied to the gate WG of the write transistor WT through the write word line WWL to turn on the write transistor WT, the magnitude of the positive voltage may be, for example, determined by factors such as the materials of the active layer WAL and the gate dielectric layer WGIL in the write transistor WT. Next, a high voltage or a low voltage may be applied to the drain WD of the write transistor WT through the write bit line WBL. When a high voltage is applied to the drain WD of the write transistor WT, the storage node SN formed by electrical connection between the source WS of the write transistor WT and the gate RG of the read transistor RT may constitute a storage capacitor, so that the charge may reach the gate RG of the read transistor RT from the write bit line WBL through the drain WD, the active layer WAL, and the source WS of the write transistor WT, and be stored in the storage capacitor, that is, the digit “1” is written to the memory cell. In contrast, when a low voltage is applied to the drain WD of the write transistor WT, the charge may pass from the gate RG of the read transistor RT through the source WS, the active layer WAL, and the drain WD of the write transistor WT, and flows out from the write bit line WBL, that is, the digit “0” is written to the memory cell.

In addition, when it is desired to execute a read operation on the DRAM device 10a, the following steps may be performed, for example, but the disclosure is not limited thereto. By applying a specific voltage to the source RS of the read transistor RT through the read word line RWL, if the data stored in the storage node SN is the digit “1”, the read transistor RT is in a low resistance state, so that the read transistor RT may be turned on, and a large current reaching the read bit line RBL via the read word line RWL through the turned-on read transistor RT is read. In contrast, if the data stored in the storage node SN is the digit “0”, the read transistor RT is in a high resistance state, so that the read transistor RT is turned off, and a small current reaching the read bit line RBL via the read word line RWL through the turned-off read transistor RT is read.

In the embodiment, the DRAM device 10a further includes a dielectric layer ILD1, a dielectric layer ILD2, and a dielectric layer ILD3.

The dielectric layer ILD1 is, for example, disposed on the substrate SB. In the embodiment, the dielectric layer ILD1 includes a dielectric layer ILD11 and a dielectric layer ILD12, the dielectric layer ILD11 is disposed on the gate WG of the write transistor WT, and the dielectric layer ILD12 is disposed on the gate RG of the read transistor RT. From another perspective, the gate WG is disposed between the dielectric layer ILD11 and the substrate SB in the normal direction n of the substrate SB, and the gate RG is disposed between the dielectric layer ILD12 and the substrate SB in the normal direction n of the substrate SB. The material of the dielectric layer ILD1 may include, for example, silicon oxide, silicon nitride, silicon oxynitride or a combination thereof, but the disclosure is not limited thereto.

The dielectric layer ILD2 is, for example, disposed on the substrate SB. In the embodiment, the dielectric layer ILD2 includes a dielectric layer ILD21 and a dielectric layer ILD22, the dielectric layer ILD21 is disposed on a sidewall of the gate WG of the write transistor WT, and the dielectric layer ILD22 is disposed on a sidewall of the gate RG of the read transistor RT. From another perspective, the dielectric layer ILD21 is disposed on the sidewall of the gate WG in the second direction d2, and the dielectric layer ILD22 is disposed on the sidewall of the gate RG in the second direction d2. In some embodiments, the dielectric layer ILD21 may extend toward the first direction d1 together with the write word line WWL, but the disclosure is not limited thereto. In the embodiment, the dielectric layer ILD21 includes the gate dielectric layer WGIL disposed between the active layer WAL and the gate WG of the write transistor WT, and the dielectric layer ILD22 includes the gate dielectric layer RGIL disposed between the active layer RAL and the gate RG of the read transistor RT, and the descriptions are not repeated here. The material of the dielectric layer ILD2 may include, for example, silicon oxide, silicon nitride, silicon oxynitride or a combination thereof, but the disclosure is not limited thereto.

The dielectric layer ILD3 is, for example, disposed on the substrate SB, and may be, for example, disposed between the adjacent write word line WWL (the gate WG of the write transistor WT) and the gate RG of the read transistor RT. In the embodiment, the dielectric layer ILD3 at least exposes a part of the active layer WAL of the write transistor WT and a part of the active layer RAL of the read transistor RT, so that the active layer WAL and the active layer RAL may be electrically connected to the drain WD of the write transistor WT and the drain RD of the read transistor RT, respectively. The material of the dielectric layer ILD3 may include, for example, silicon oxide, silicon nitride, silicon oxynitride or a combination thereof, but the disclosure is not limited thereto.

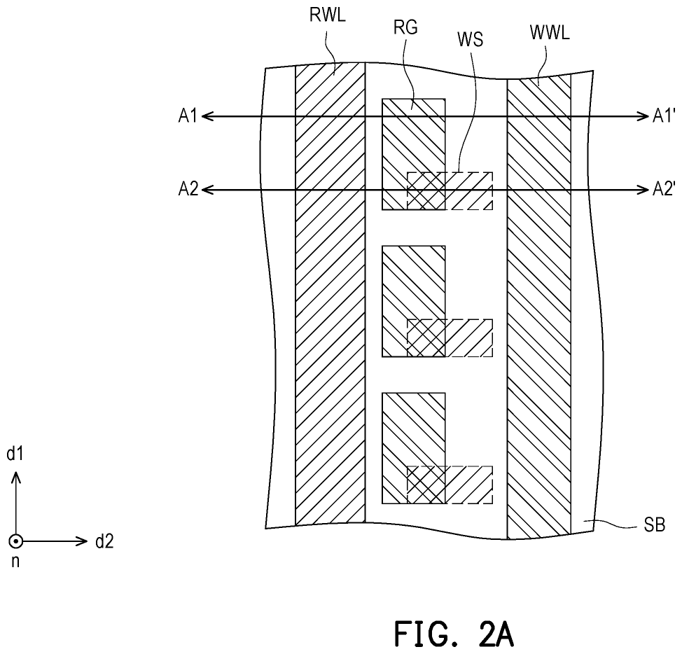

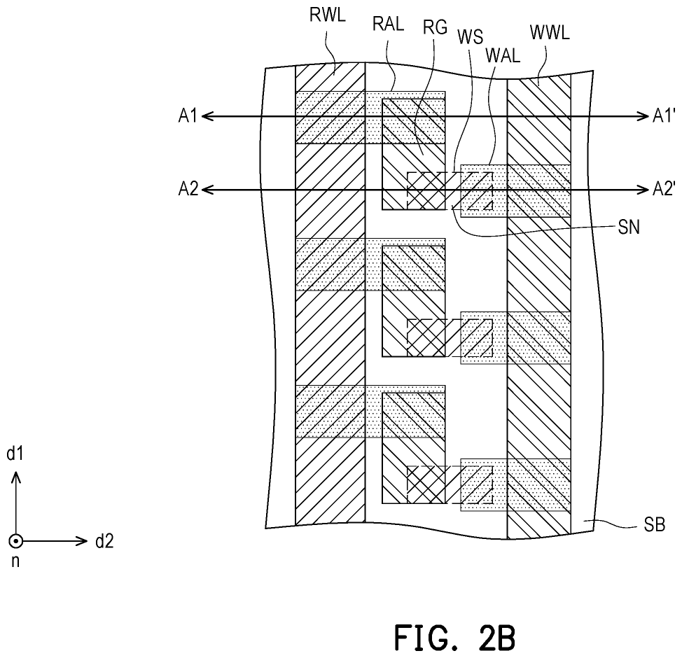

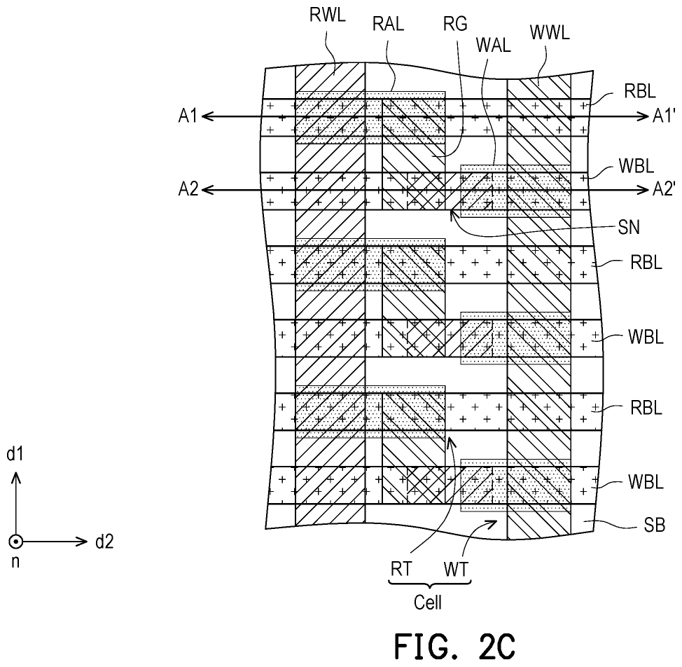

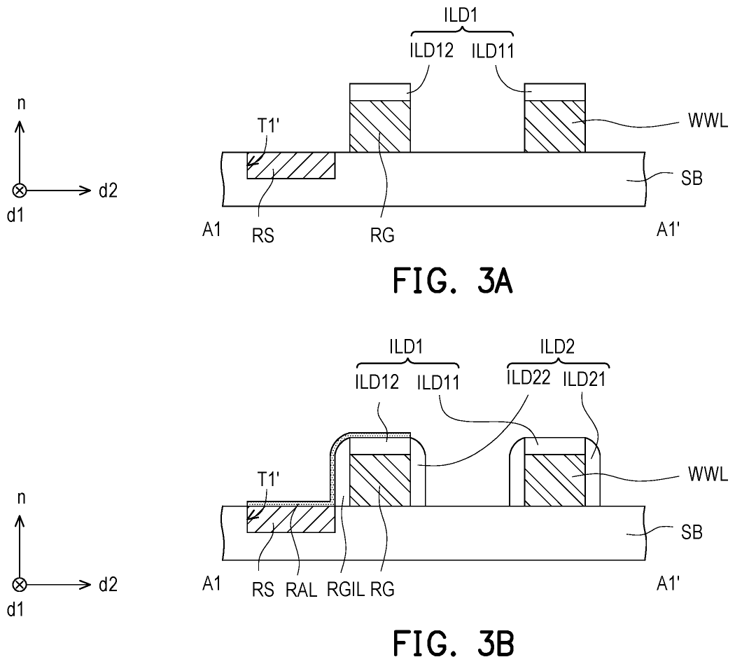

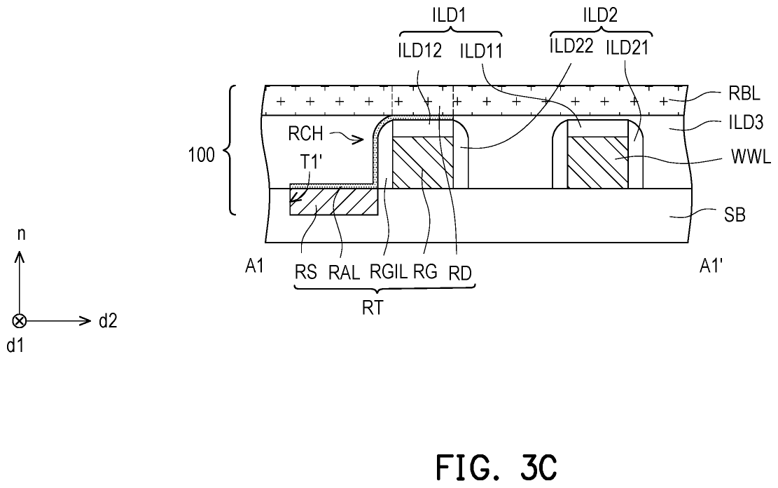

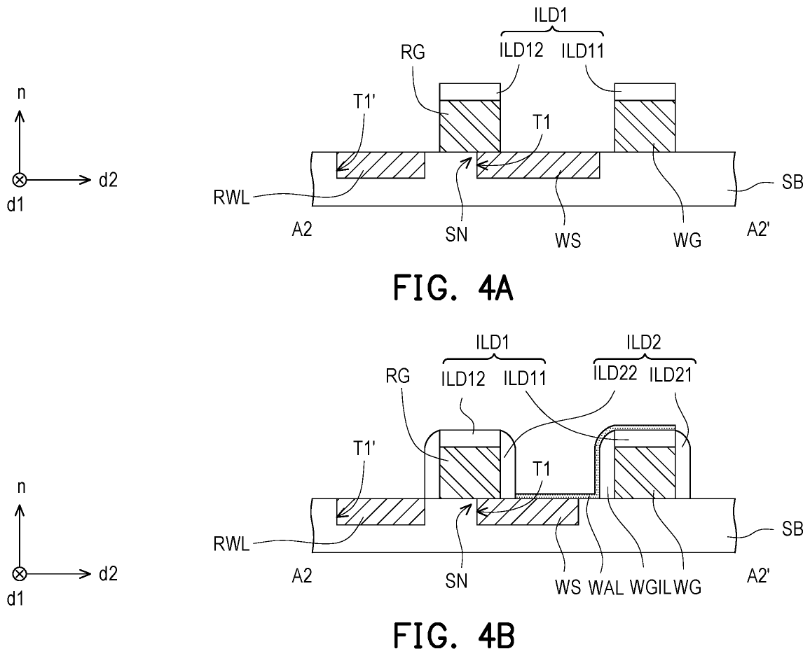

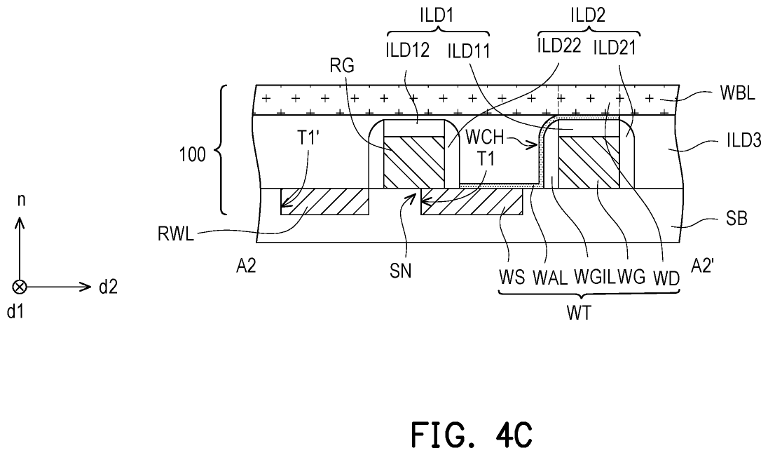

FIGS. 2A to 2C are schematic top views of a method for forming a DRAM device according to the first embodiment of the disclosure, FIGS. 3A to 3C are each a schematic cross-sectional view taken along a section line A1-A1′ in FIGS. 2A to 2C, and FIGS. 4A to 4C are each a schematic cross-sectional view taken along a section line A2-A2′ in FIGS. 2A to 2C. It should be noted that the embodiment of FIGS. 2A to 2C, FIGS. 3A to 3C, and FIGS. 4A to 4C may use the reference numerals and a part of the contents of the embodiment of FIGS. 1A to 1C, and the same or similar reference numerals are used to denote the same or similar elements, and the descriptions of the same technical contents are omitted.

Please refer to FIGS. 2A, 3A, and 4A at the same time. The write word line WWL (including the gate WG of the write transistor WT), the gate RG of the read transistor RT, and the dielectric layer ILD1 are formed on the substrate SB, and the write word line WWL and the gate RG of the read transistor RT belong to the same layer (a first conductor layer). The material of the substrate SB may refer to the foregoing embodiment, and the descriptions are not repeated here.

In the embodiment, before the write word line WWL, the gate RG of the read transistor RT, and the dielectric layer ILD1 are formed on the substrate SB, the source WS of the write transistor WT and the read word line RWL (including the source RS of the read transistor RT) are formed in the substrate SB. In some embodiments, the method for forming the source WS of the write transistor WT and the read word line RWL in the substrate SB may include the following steps, but the disclosure is not limited thereto. Firstly, the trench T1 and the trench T1′ are formed on the substrate SB, and the trench T1 and the trench T1′ may be formed, for example, by performing a patterning process to remove a part of the substrate SB. Next, a conductive material layer (not shown) filled in the trench T1 and the trench T1′ is formed on the substrate SB. Then, the conductive material layer outside the trench T1 and the trench T1′ is removed to form the source WS of the write transistor WT and the read word line RWL in the trench T1 and the trench T1′, respectively.

In the embodiment, the formed gate RG of the read transistor RT is in partial contact with the source WS of the write transistor WT in the normal direction n of the substrate SB, so that the gate RG of the read transistor RT is electrically connected to the source WS of the write transistor WT to form the storage node SN.

In some embodiments, the method for forming the write word line WWL (including the gate WG of the write transistor WT), the gate RG of the read transistor RT, and the dielectric layer ILD1 on the substrate SB may include the following steps, but the disclosure is not limited thereto. Firstly, a conductive material layer (not shown) and a dielectric material layer (not shown) covering the substrate SB are sequentially formed on the substrate SB. Next, a part of the dielectric material layer is removed by performing a patterning process to form the dielectric layer ILD1. Then, an etching process is performed with the dielectric layer ILD1 as a mask to remove a part of the conductive material layer, so as to respectively form the write word line WWL and the gate RG of the read transistor RT. The write word line WWL extends, for example, along the first direction d1. In addition, the dielectric layer ILD1 is, for example, disposed on the write word line WWL and the gate RG of the read transistor RT. From another perspective, the write word line WWL and the gate RG of the read transistor RT are, for example, located between the substrate SB and the dielectric layer ILD1.

In the embodiment, a part of the write word line WWL may serve as the gate WG of the write transistor WT, that is, the gate WG is directly connected to the write word line WWL, but the disclosure is not limited thereto. In addition, the dielectric layer ILD1 includes the dielectric layer ILD11 and the dielectric layer ILD12, the dielectric layer ILD11 is, for example, at least disposed on the gate WG of the write transistor WT, and the dielectric layer ILD12 is, for example, disposed on the gate RG of the read transistor RT.

In the embodiment, the dielectric layer ILD2 is further formed on the substrate SB, and the dielectric layer ILD2 is disposed on the substrate SB and is located on a sidewall of the write word line WWL and the sidewall of the gate RG of the read transistor RT. In detail, the dielectric layer ILD2 at least includes, for example, the dielectric layer ILD21 and the dielectric layer ILD22, the dielectric layer ILD21 is, for example, at least located on the sidewall of the gate WG of the write transistor WT, and the dielectric layer ILD22 is, for example, located on the sidewall of the gate RG of the read transistor RT. In the embodiment, the dielectric layer ILD21 may extend toward the first direction d1 together with the write word line WWL, but the disclosure is not limited thereto. In addition, the dielectric layer ILD2 at least exposes, for example, a part of the source WS of the write transistor WT and a part of the source RS of the read transistor RT.

Please refer to FIGS. 2B, 3B, and 4B at the same time. The active layer WAL of the write transistor WT and the active layer RAL of the read transistor RT are formed on the substrate SB. The active layer WAL of the writing transistor WT covers a part of the dielectric layer ILD11, a part of the dielectric layer ILD21 (the gate dielectric layer WGIL) close to the source WS, and the source WS, and the active layer RAL of the read transistor RT covers a part of the dielectric layer ILD12, a part of the dielectric layer ILD22 (the gate dielectric layer RGIL) close to the source RS, and the source RS. In some embodiments, the active layer WAL of the write transistor WT may at least further cover a part of the dielectric layer ILD21 away from the source WS, and the active layer RAL of the read transistor RT may at least further cover a part of the dielectric layer ILD22 away from the source RS, but the disclosure is not limited thereto.

Please refer to FIGS. 2C, 3C, and 4C at the same time. The dielectric layer ILD3, the write bit line WBL (including the drain WD of the write transistor WT), and the read bit line RBL (including the drain RD of the read transistor RT) are formed on the substrate SB. The dielectric layer ILD3 is disposed on the substrate SB, and the write bit line WBL and the read bit line RBL are disposed on the dielectric layer ILD3. From another perspective, the dielectric layer ILD3 is located between the write bit line WBL (or the read bit line RBL) and the substrate SB. In some embodiments, the method for forming the dielectric layer ILD3, the write bit line WBL, and the read bit line RBL on the substrate SB may include the following steps, but the disclosure is not limited thereto. Firstly, a dielectric material layer (not shown) covering the active layer WAL of the write transistor WT, the active layer RAL of the read transistor RT, the dielectric layer ILD1, and the dielectric layer ILD2 is formed on the substrate SB. Next, a part of the dielectric material layer is removed by performing a planarization process (for example, including a grinding process, an etching process or a combination thereof) to form the dielectric layer ILD3. The dielectric layer ILD3 at least exposes a part of the active layer WAL of the write transistor WT and a part of the active layer RAL of the read transistor RT. Then, the write bit line WBL and the read bit line RBL are formed on the dielectric layer ILD3. In the embodiment, the write bit line WBL and the read bit line RBL extend toward the second direction d2, but the disclosure is not limited thereto. In addition, a part of the write bit line WBL may serve as, for example, the drain WD of the write transistor WT, and a part of the read bit line RBL may serve as, for example, the drain RD of the read transistor RT, that is, the drain WD is directly connected to the write bit line WBL, and the drain RD is directly connected to the read bit line RBL, but the disclosure is not limited thereto. In addition, the drain WD of the write transistor WT is electrically connected to the active layer WAL exposed by the dielectric layer ILD3, and the drain RD of the read transistor RT is electrically connected to the active layer RAL exposed by the dielectric layer ILD3.

So far, the fabrication of the memory device layer 100 is completed. However, the method for forming the memory device layer 100 of the disclosure is not limited thereto.

Afterwards, referring to FIGS. 1B and 1C, multiple memory device layers 100 are stacked in the normal direction n of the substrate SB to form the DRAM device 10a having a three-dimensional structure, thereby improving the storage capacity of the DRAM device 10a while reducing the occupied area of the DRAM device 10a, so as to facilitate the integration of the DRAM device 10a. In some embodiments, the isolation layer IL is disposed between the adjacent memory device layers 100. The material of the isolation layer IL may refer to the foregoing embodiment, and the descriptions are not repeated here. It should be noted that although FIG. 1B merely shows three memory device layers 100, the disclosure does not limit the number of memory device layers 100 included in the DRAM device 10a.

So far, the fabrication of the DRAM device 10a is completed. Although the method for forming the DRAM device 10a of the embodiment is described by taking the above method as an example, the method for forming the DRAM device of the disclosure is not limited thereto.

Based on this, the DRAM device 10a of the embodiment does not need to be provided with an additional capacitor, and the storage node SN configured to store the data is formed by making the gate RG of the read transistor RT connected to the source WS of the write transistor WT. Therefore, the DRAM device 10a has a simplified structure, so that the density of the DRAM device 10a may be improved.

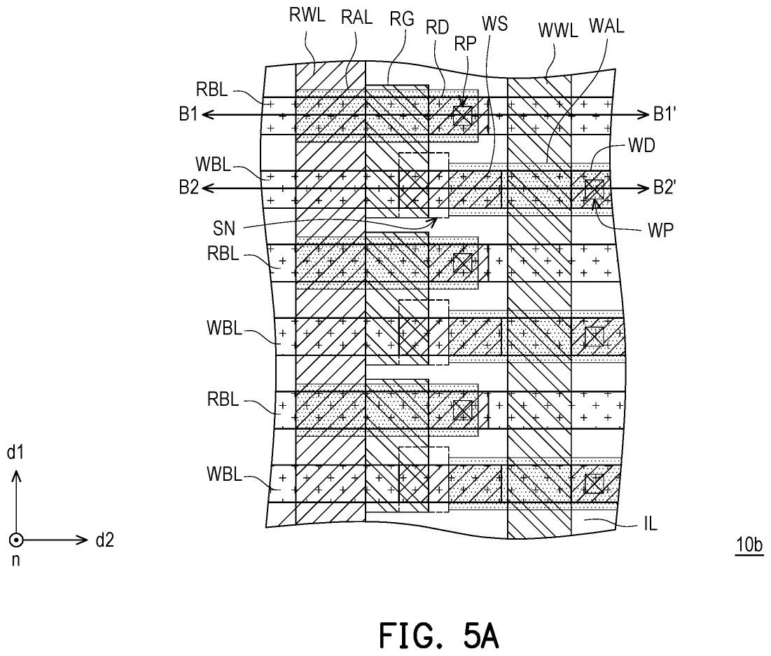

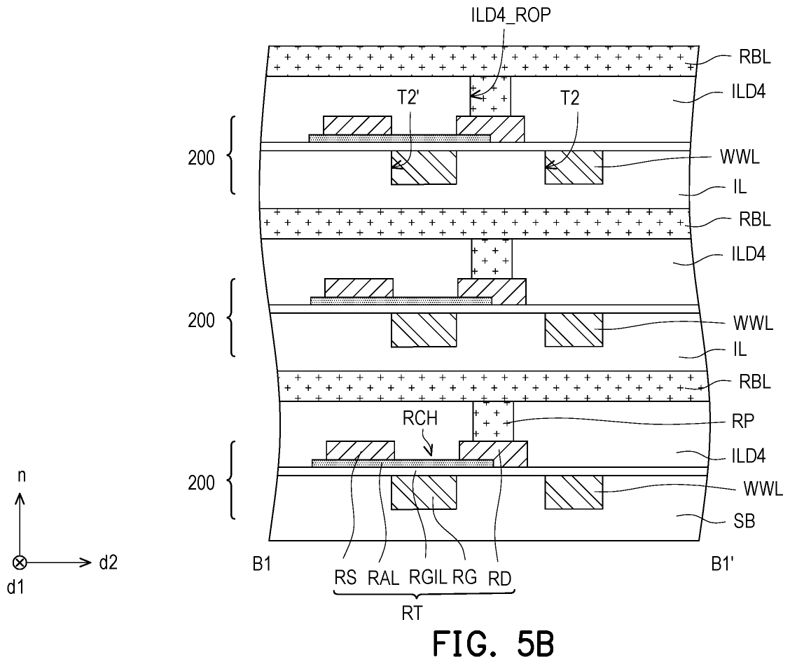

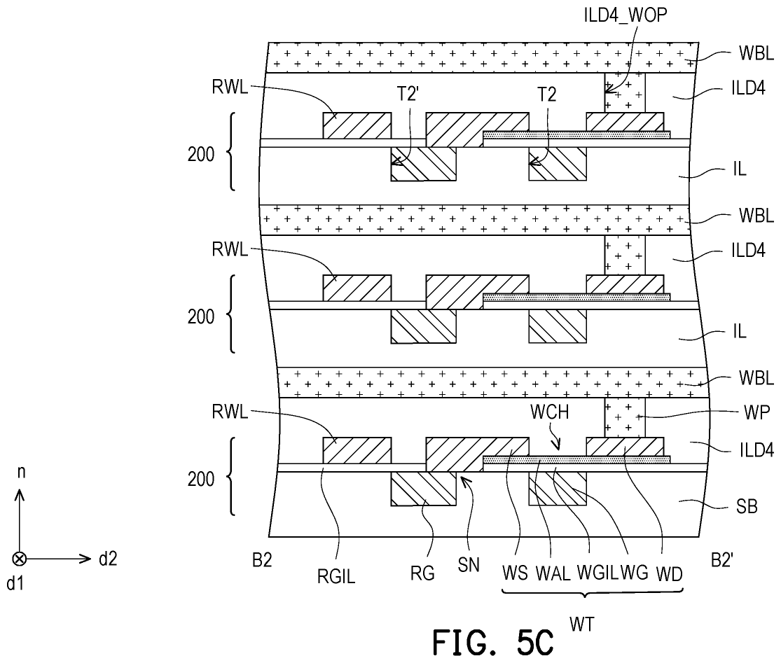

FIG. 5A is a schematic top view of a DRAM device according to a second embodiment of the disclosure, FIG. 5B is a schematic cross-sectional view taken along a section line B1-B1′ of FIG. 5A, and FIG. 5C is a schematic cross-sectional view taken along a section line B2-B2′ of FIG. 5A.

Please refer to FIGS. 5A, 5B, and 5C at the same time. The main difference between a DRAM device 10b of the embodiment and the DRAM device 10a lies in: (1) The write word line WWL (including the gate WG of the write transistor WT) and the gate RG of the read transistor RT are respectively disposed in a trench T2 and a trench T2′ of the substrate SB; (2) The write transistor WT and the read transistor RT in a memory device layer 200 are horizontal transistors; (3) The read word line RWL and the source WS and the drain WD of the write transistor WT belong to the same layer; (4) The write bit line WBL and the read bit line RBL are electrically connected to the drain WD of the write transistor WT and the drain RD of the read transistor RT through a plug WP and a plug RP, respectively.

In the aforementioned (1), the write word line WWL and the gate RG of the read transistor RT are respectively disposed in the trench T2 and the trench T2′ of the substrate SB, that is, the write word line WWL of the embodiment is a buried word line, and the gate RG of the read transistor RT is a buried gate, but the disclosure is not limited thereto. In addition, a part of the write word line WWL may serve as the gate WG of the write transistor WT. Based on this, the write word line WWL may be directly connected to the gate WG of the write transistor WT, thereby improving the density of the DRAM device 10b.

In the aforementioned (2), the gate dielectric layer WGIL of the write transistor WT is, for example, disposed on the substrate SB and covers the gate WG, and the gate dielectric layer RGIL of the read transistor RT is, for example, disposed on the substrate SB and covers the gate RG. For example, the gate dielectric layer WGIL of the write transistor WT may be disposed on the gate WG in the normal direction n of the substrate SB, and the gate dielectric layer RGIL of the read transistor RT may be disposed on the gate RG in the normal direction n of the substrate SB, but the disclosure is not limited thereto. The active layer WAL of the write transistor WT is, for example, disposed on the gate dielectric layer WGIL and is disposed corresponding to the gate WG. The portion of the active layer WAL overlapping the gate WG may be, for example, the channel layer WCH of the write transistor WT. From another perspective, the gate dielectric layer WGIL is, for example, disposed between the gate WG and the channel layer WCH of the active layer WAL. Similarly, the active layer RAL of the read transistor RT is, for example, disposed on the gate dielectric layer RGIL and is disposed corresponding to the gate RG. The portion of the active layer RAL overlapping the gate RG may be, for example, the channel layer RCH of the read transistor RT. From another perspective, the gate dielectric layer RGIL is, for example, disposed between the gate RG and the channel layer RCH of the active layer RAL. The source WS and the drain WD of the write transistor WT and the source RS and the drain RD of the read transistor RT belong to, for example, the same layer, and partially cover the channel layer WCH of the write transistor WT and the channel layer RCH of the read transistor RT in the normal direction n of the substrate SB, respectively.

In the embodiment, the channel layer WCH of the write transistor WT and the channel layer RCH of the read transistor RT extend along the second direction d2, and are disposed corresponding to the gate WG and the gate RG, respectively, in the normal direction n of the substrate SB. Therefore, the write transistor WT and the read transistor RT of the embodiment are horizontal transistors, but the disclosure is not limited thereto.

In the aforementioned (3), a part of the read word line RWL may serve as the source RS of the read transistor RT, and the drain RD of the read transistor RT and the source WS and the drain WD of the write transistor WT also belong to the same layer. Based on this, the read word line RWL may be directly connected to the source RS of the read transistor RT, thereby increasing the density of the DRAM device 10b.

In the aforementioned (4), the write bit line WBL and the read bit line RBL do not belong to the same layer as the drain WD of the write transistor WT and the drain RD of the read transistor RT. In the embodiment, a dielectric layer ILD4 is disposed between the write bit line WBL and the read bit line RBL and the drain WD of the write transistor WT and the drain RD of the read transistor RT. The dielectric layer ILD4 has, for example, an opening ILD4_WOP and an opening ILD4_ROP, the opening ILD4_WOP and the opening ILD4_ROP expose, for example, a part of the drain WD of the write transistor WT and a part of the drain RD of the read transistor RT, respectively. Based on this, through the plug WP of ILD4_WOP disposed in the opening ILD4_WOP and the plug RP disposed in the opening ILD4_ROP, the write bit line WBL and the read bit line RBL of the embodiment may be electrically connected to the drain WD of the write transistor WT and the drain RD of the read transistor RT, respectively.

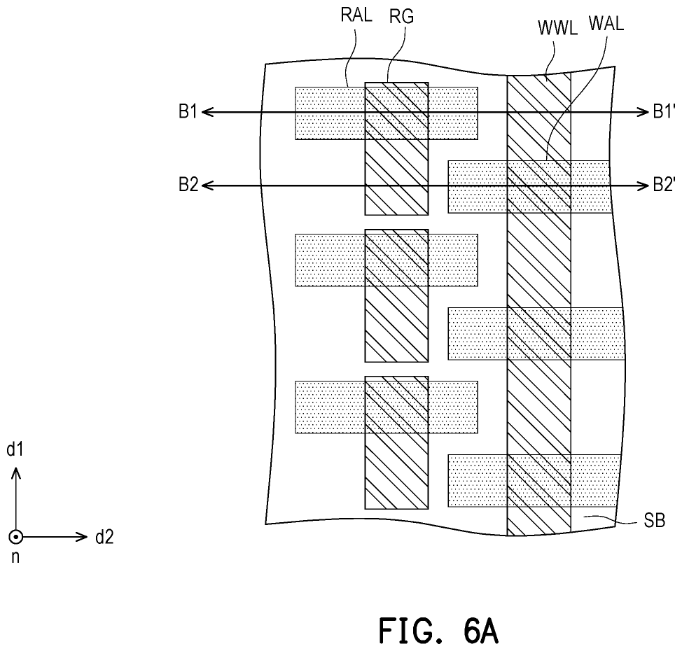

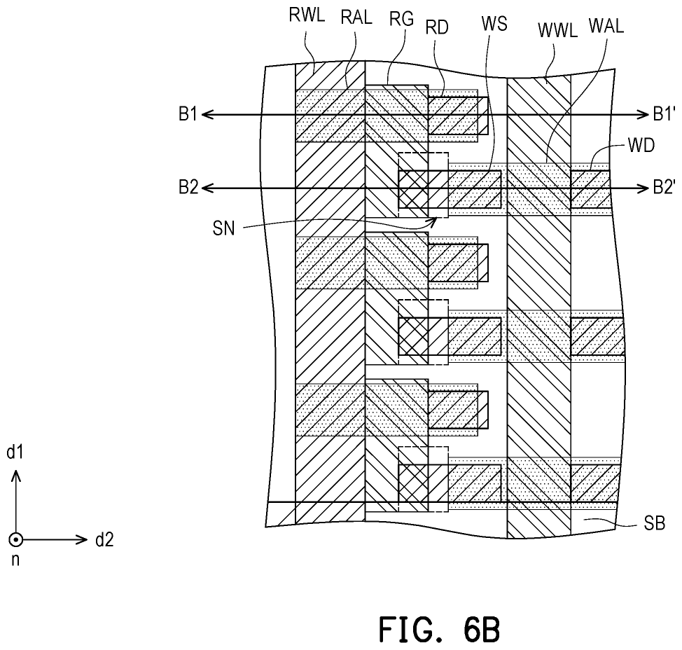

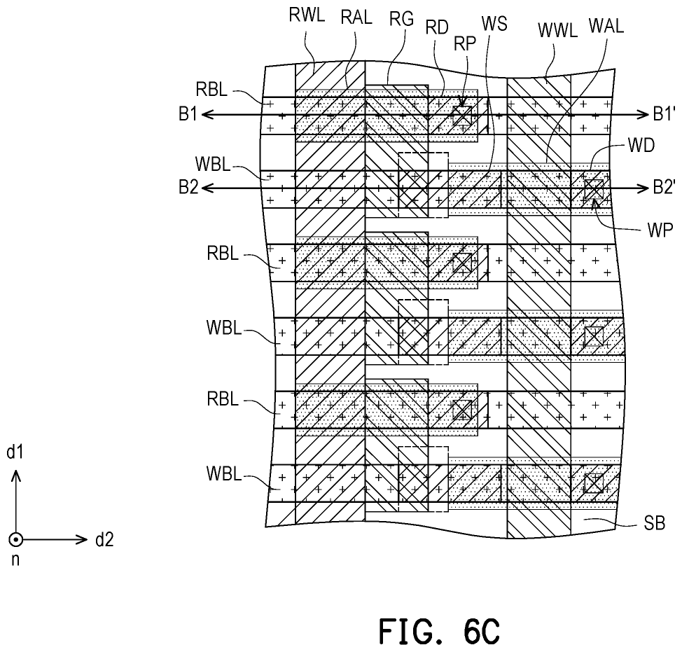

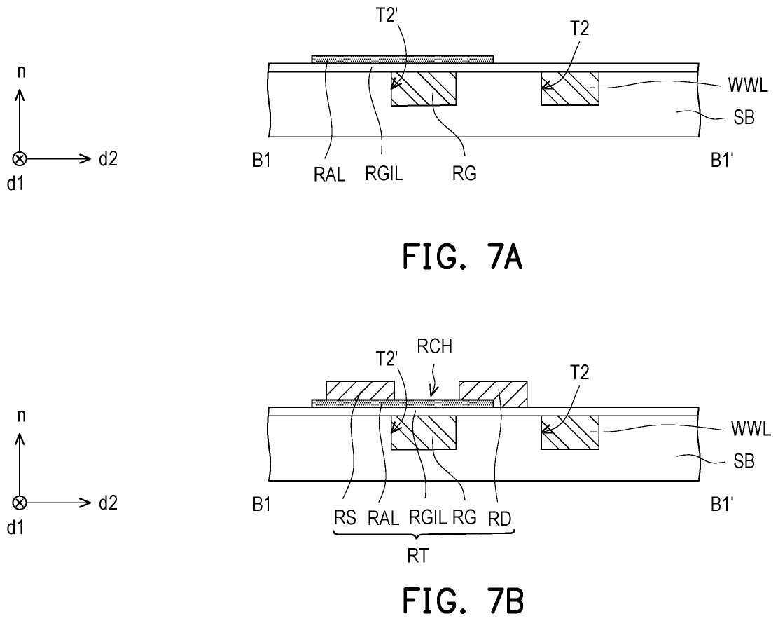

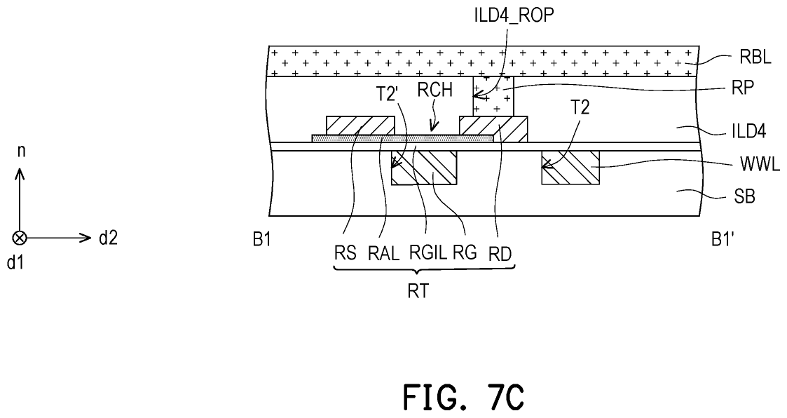

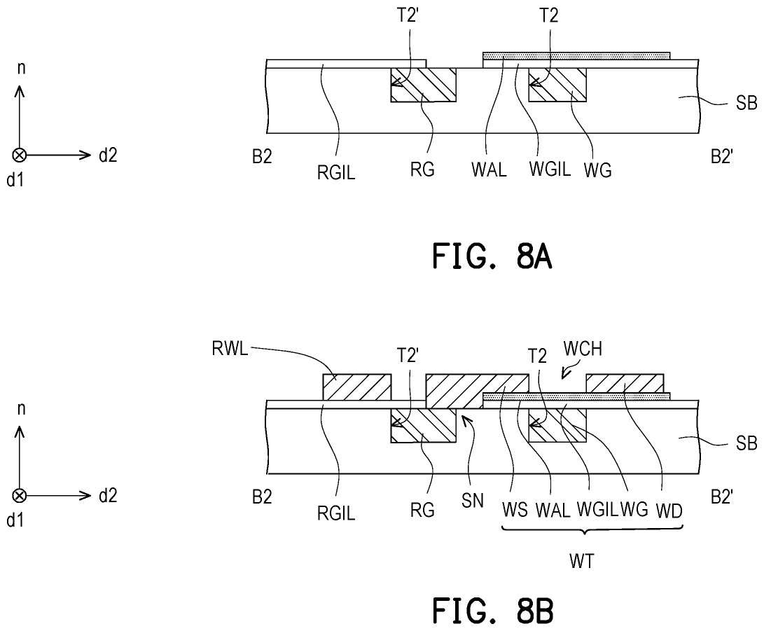

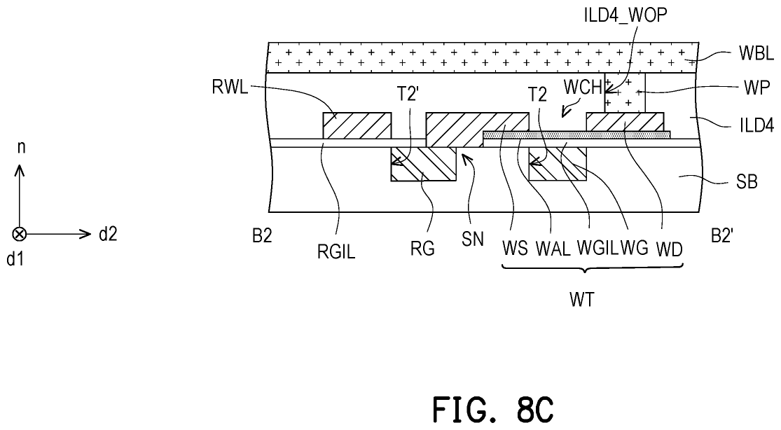

FIGS. 6A to 6C are schematic top views of a method for forming a DRAM device according to the second embodiment of the disclosure, and FIGS. 7A to 7C are each a schematic cross-sectional view taken along a section line B1-B1′ in FIGS. 6A to 6C, and FIGS. 8A to 8C are each a schematic cross-sectional view taken along a section line B2-B2′ in FIGS. 6A to 6C. It should be noted that the embodiment of FIGS. 6A to 6C, FIGS. 7A to 7C, and FIGS. 8A to 8C may use the reference numerals and a part of the contents of the embodiment of FIGS. 5A to 5C, and the same or similar reference numerals are used to denote the same or similar elements, and the descriptions of the same technical contents are omitted.

Referring to FIGS. 6A, 7A, and 8A at the same time, the substrate SB having the trench T2 and the trench T2′ is provided.

In the embodiment, the write word line WWL and the gate RG of the read transistor RT are further formed in the substrate SB, the write word line WWL extends toward the first direction d1, and a part of the write word line WWL may serve as the gate WG of the write transistor WT. In some embodiments, the method for forming the write word line WWL and the gate RG of the read transistor RT in the substrate SB may include the following steps, but the disclosure is not limited thereto. Firstly, the trench T2 and the trench T2′ are formed in the substrate SB, and the trench T2 and the trench T2′ may be formed, for example, by performing a patterning process to remove a part of the substrate SB. Next, a conductive material layer (not shown) filled in the trench T2 and the trench T2′ is formed on the substrate SB. Then, the conductive material layer outside the trench T2 and the trench T2′ is removed to form the write word line WWL and the gate RG of the read transistor RT.

In the embodiment, the gate dielectric layer WGIL and the active layer WAL of the write transistor WT and the gate dielectric layer RGIL and the active layer RAL of the read transistor RT are further formed on the substrate SB. In some embodiments, the method for forming the gate dielectric layer WGIL, the active layer WAL, the gate dielectric layer RGIL, and the active layer RAL on the substrate SB may include the following steps, but the disclosure is not limited thereto. Firstly, a dielectric material layer (not shown) covering the substrate SB and an active material layer (not shown) are formed on the substrate SB. Next, a part of the active material layer is removed by performing a patterning process to respectively form the active layer WAL and the active layer RAL, the active layer WAL is disposed corresponding to the gate WG of the write transistor WT, and the active layer RAL is disposed corresponding to the gate RG of the read transistor RT. Then, a part of the dielectric material layer is removed by performing a patterning process to respectively form the gate dielectric layer WGIL and the gate dielectric layer RGIL, the gate dielectric layer WGIL covers the write word line WWL disposed in the trench T2, and the gate dielectric layer RGIL partially covers the gate RG of the read transistor RT disposed in the trench T2′. That is, the gate dielectric layer RGIL may expose a part of the gate RG of the read transistor RT.

Please refer to FIGS. 6B, 7B, and 8B at the same time. The source WS and the drain WD of the write transistor WT, the source RS and the drain RD of the read transistor RT, and the read word line RWL are formed on the substrate SB. In some embodiments, the method for forming the source WS and the drain WD of the write transistor WT, the source RS and the drain RD of the read transistor RT, and the read word line RWL on the substrate SB may include the following steps, but the disclosure is not limited thereto. Firstly, a covering conductive material layer (not shown) is formed on the substrate SB. Next, a part of the conductive material layer is removed by performing a patterning process. In the embodiment, the source WS and the drain WD of the write transistor WT are separated from each other, and the source WS of the write transistor WT is connected to the exposed gate RG of the read transistor RT, so that the storage node SN is formed and may constitute a storage capacitor. In addition, the source WS and the drain WD partially cover the active layer WAL and are electrically connected to the active layer WAL. Similarly, in the embodiment, the source RS and the drain RD of the read transistor RT are separated from each other, and the source RS and the drain RD partially cover the active layer RAL and are electrically connected to the active layer RAL.

In the embodiment, the read word line RWL extends toward the first direction d1, that is, the read word line RWL and the write word line WWL extend toward the same direction, but the disclosure is not limited thereto. In addition, a part of the read word line RWL may serve as the source RS of the read transistor RT, that is, the source RS is directly connected to the read word line RWL, but the disclosure is not limited thereto.

So far, the fabrication of the memory device layer 200 is completed. However, the method for forming the memory device layer 200 of the disclosure is not limited thereto.

Please refer to FIGS. 6C, 7C, and 8C at the same time. The dielectric layer ILD4, the write bit line WBL, and the read bit line RBL are formed on the substrate SB. The dielectric layer ILD4 is disposed on the substrate SB, and the write bit line WBL and the read bit line RBL are disposed on the dielectric layer ILD4. From another perspective, the dielectric layer ILD4 is located between the write bit line WBL (or the read bit line RBL) and the substrate SB. In some embodiments, the method for forming the dielectric layer ILD4, the write bit line WBL, and the read bit line RBL on the substrate SB may include the following steps, but the disclosure is not limited thereto. Firstly, a dielectric material layer (not shown) at least covering the source WS, the drain WD, and the active layer WAL of the write transistor WT and the source RS, the drain RD, and the active layer RAL of the read transistor RT is formed on the substrate SB. Next, a part of the dielectric material layer is removed by performing a planarization process (for example, including a grinding process, an etching process or a combination thereof), so that the dielectric material layer has a flat top surface. Then, a part of the dielectric material layer is removed by performing a patterning process (for example, including a grinding process, an etching process or a combination thereof) to form the dielectric layer ILD4. The dielectric layer ILD4 has the opening ILD4_WOP and the opening ILD4_ROP, and the opening ILD4_WOP and the opening ILD4_ROP respectively expose, for example, a part of the drain WD of the write transistor WT and a part of the drain RD of the read transistor RT. Furthermore, the plug WP and the plug RP are respectively disposed in the opening ILD4_WOP and the opening ILD4_ROP, which may be formed, for example, by filling a conductive layer. Afterwards, the write bit line WBL and the read bit line RBL are formed on the dielectric layer ILD4. The write bit line WBL and the read bit line RBL are connected to the plug WP and the plug RP, respectively, so that the write bit line WBL and the read bit line RBL may be electrically connected to the drain WD of the write transistor WT and the drain RD of the read transistor RT, respectively. In the embodiment, the write bit line WBL and the read bit line RBL extend toward the second direction d2, but the disclosure is not limited thereto.

Afterwards, referring to FIGS. 5B and 5C, multiple memory device layers 200 are stacked in the normal direction n of the substrate SB. In some embodiments, the isolation layer IL is disposed between the adjacent memory device layers 200. In addition, although not shown in FIGS. 4B and 4C, in other embodiments, other dielectric layers may be disposed between the adjacent memory device layers 200, and the disclosure is not limited thereto.

So far, the fabrication of the DRAM device 10b having a three-dimensional structure is completed. In this way, the occupied area of the DRAM device 10b may be reduced while increasing the storage capacity of the DRAM device 10b, so as to facilitate the integration of the DRAM device 10b. Although the method for forming the DRAM device 10b of the embodiment is described by taking the above method as an example, the method for forming the DRAM device of the disclosure is not limited thereto. It should be noted that although FIGS. 5B and 5C merely show three memory device layers 200, the disclosure does not limit the number of memory device layers 200 included in the DRAM device 10b.

Based on this, the DRAM device 10b of the embodiment does not need to be provided with an additional capacitor, and the storage node SN configured to store the data is formed by making the gate RG of the read transistor RT connected to the source WS of the write transistor WT. Therefore, the DRAM device 10b has a simplified structure, so that the density of the DRAM device 10b may be improved.

In summary, the disclosure provides a DRAM device having a three-dimensional structure and a method for forming the same, which includes: multiple memory device layers are stacked in the normal direction of the substrate, and the storage node configured to store the data is formed by making the gate of the read transistor connected to the source of the write transistor. Based on this, the disclosure may further reduce the occupied area of the DRAM device, and increase the density of the DRAM device.

What is claimed is:

1. A dynamic random access memory (DRAM) device, comprising:
a substrate;
a plurality of write word lines, extending toward a first direction;
a plurality of write bit lines, extending toward a second direction, wherein the second direction is orthogonal to the first direction;
a plurality of read word lines, extending toward the first direction;
a plurality of read bit lines, extending toward the second direction; and
a plurality of memory device layers, disposed on the substrate and stacked in a normal direction of the substrate, wherein each of the plurality of memory device layers comprises a plurality of memory cells, the plurality of memory cells comprise write transistors and read transistors, the write transistor is electrically connected to a corresponding write word line and a corresponding write bit line, and the read transistors is electrically connected to a corresponding read word line and a corresponding read bit line,
wherein a source of the write transistor is electrically connected to a gate of the read transistor to form a storage node.

2. The DRAM device according to claim 1, wherein materials of a channel layer of the write transistor and a channel layer of the read transistor comprise oxide semiconductors.

3. The DRAM device according to claim 2, wherein the channel layer of the write transistor and the channel layer of the read transistor extend toward the normal direction of the substrate.

4. The DRAM device according to claim 1, wherein the plurality of write word lines are disposed on the substrate.

5. The DRAM device according to claim 1, wherein the plurality of read word lines are disposed in trenches of the substrate.

6. The DRAM device according to claim 1, wherein a drain of the write transistor and the write bit line belong to the same layer, and a drain of the read transistor and the read bit line belong to the same layer.

7. A method for forming a dynamic random access memory (DRAM) device, comprising:
providing a substrate having a trench, wherein a source of a write transistor and a read word line are disposed in the trench, and the read word line extends toward a first direction and comprises a source of a read transistor;
forming a write word line and a gate of the read transistor on the substrate, wherein the write word line extends toward the first direction and comprises a gate of the write transistor, and the gate of the read transistor is connected to the source of the write transistor to form a storage node;
forming an active layer of the write transistor and an active layer of the read transistor on the substrate;
forming a write bit line and a read bit line on the substrate to form a memory device layer, wherein the write bit line and the read bit line extend toward a second direction, and the write bit line and the read bit line respectively comprise a drain of the write transistor and a drain of the read transistor; and
stacking a plurality of the memory device layers in a normal direction of the substrate,
wherein a channel layer in the active layer of the write transistor and the gate of the write transistor are disposed correspondingly in the second direction, and a channel layer in the active layer of the read transistor and the gate of the read transistor are disposed correspondingly in the second direction.

8. The method for forming the DRAM device according to claim 7, wherein before the active layer of the write transistor and the active layer of the read transistor are formed, a first dielectric layer respectively formed on each of the gate of the write transistor and the gate of the read transistor is further comprised.

9. The method for forming the DRAM device according to claim 7, wherein before the active layer of the write transistor and the active layer of the read transistor are formed, a second dielectric layer respectively formed on each of a sidewall of the gate of the write transistor and a sidewall of the gate of the read transistor is further comprised.

10. The method for forming the DRAM device according to claim 7, wherein before the write bit line and the read bit line are formed on the substrate, a third dielectric layer is formed on the substrate, wherein the third dielectric layer exposes a part of the active layer of the write transistor and a part of the active layer of the read transistor.

11. The method for forming the DRAM device according to claim 7, wherein an isolation layer is disposed between adjacent memory device layers in the normal direction of the substrate.

12. A method for forming a dynamic random access memory (DRAM) device, comprising:
providing a substrate having a trench, wherein a gate of a read transistor and a write word line are disposed in the trench, and the write word line comprises a gate of a write transistor;
forming a first dielectric layer and an active layer of the write transistor and a first dielectric layer and an active layer of the read transistor on the substrate;
forming a source and a drain of the write transistor, a drain of the read transistor, and a read word line on the substrate to form a memory device layer, wherein the read word line extends toward a first direction and comprises a source of the read transistor, and the gate of the read transistor is connected to the source of the write transistor to form a storage node;
forming a second dielectric layer on the substrate, wherein the second dielectric layer exposes an opening for the drain of the write transistor and the drain of the read transistor to be connected to a write bit line and a read bit line, respectively;
forming the write bit line and the read bit line on the second dielectric layer, wherein the write bit line and the read bit line extend toward a second direction, the write bit line is electrically connected to the drain of the write transistor with a first plug, and the read bit line is electrically connected to the drain of the read transistor with a second plug; and
stacking a plurality of the memory device layers in a normal direction of the substrate.

13. The method for forming the DRAM device according to claim 12, wherein the write bit line and the read bit line are electrically connected to the drain of the write transistor and the drain of the read transistor through the first plug and the second plug disposed in the second dielectric layer, respectively.

14. The method for forming the DRAM device according to claim 12, wherein an isolation layer is disposed between adjacent memory device layers in the normal direction of the substrate.
